(19) United States
(12) Patent Application Publication
(10) Pub. No.: US 2019/0013198 A1
(43) Pub. Date: Jan. 10, 2019

(54) SILICON CARBIDE EPITAXIAL SUBSTRATE AND METHOD FOR MANUFACTURING SILICON CARBIDE SEMICONDUCTOR DEVICE

(71) Applicant: Sumitomo Electric Industries, Ltd., Osaka-shi (JP)

(72) Inventors: Hironori Itoh, Itami-shi (JP); Taro Nishiguchi, Itami-shi (JP); Kenji Hiratsuka, Itami-shi (JP)

(21) Appl. No.: 16/069,029

(22) PCT Filed: Dec. 14, 2016
(86) PCT No.: PCT/JP2016/087209

§ 371 Date: Jul. 10, 2018

(30) Foreign Application Priority Data
Feb. 10, 2016 (JP) 2016-023939

(51) Int. Cl. H01L 21/02; C30B 29/36; H01L 29/66; H01L 29/16; H01L 29/167

(52) U.S. Cl. CPC H01L 21/02529; C30B 29/36; H01L 29/66068; H01L 21/02378; H01L 29/167; H01L 21/0262; H01L 21/02658; H01L 21/02576; H01L 29/1608; H01L 21/02634

(57) ABSTRACT

A silicon carbide epitaxial substrate includes: a silicon carbide single crystal substrate; a first silicon carbide layer on the silicon carbide single crystal substrate, the first silicon carbide layer having a first concentration of carriers; and a second silicon carbide layer on the first silicon carbide layer, the second silicon carbide layer having a second concentration of carriers. A transition region in which the concentration of the carriers is changed between the first concentration and the second concentration has a width of less than or equal to 1 μm. A ratio of a standard deviation of the second concentration to an average value of the second concentration is less than or equal to 5%, the ratio being defined as uniformity of the second concentration in a central region. The central region has an arithmetic mean roughness of less than or equal to 0.5 nm.

### TECHNICAL FIELD

The present disclosure relates to a silicon carbide epitaxial substrate and a method for manufacturing a silicon carbide semiconductor device. The present application claims a priority based on Japanese Patent Application No. 2016-023939 filed on Feb. 10, 2016, the entire content of which is incorporated herein by reference.

### BACKGROUND ART

Japanese Patent Laying-Open No. 2014-103363 (Patent Document 1) discloses a method for manufacturing a silicon carbide semiconductor substrate. This manufacturing method includes forming a first silicon carbide layer and a second silicon carbide layer using ammonia gas and nitrogen gas for dopant gas.

### CITATION LIST

### Patent Document

PTD 1: Japanese Patent Laying-Open No. 2014-103363

### SUMMARY OF INVENTION

A silicon carbide epitaxial substrate according to the present disclosure includes: a silicon carbide single crystal substrate having a first main surface; a first silicon carbide layer on the silicon carbide single crystal substrate, the first silicon carbide layer having a first concentration of carriers; and a second silicon carbide layer on the first silicon carbide layer, the second silicon carbide layer having a second concentration of carriers smaller than the first concentration, the second silicon carbide layer including a second main surface opposite to the first main surface. In a concentration profile of the carriers along a layering direction in which the first silicon carbide layer and the second silicon carbide layer are layered, a transition region in which the concentration of the carriers is changed between the first concentration and the second concentration has a width of less than or equal to 1 μm. A ratio of a standard deviation of the second concentration to an average value of the second concentration is less than or equal to 5%, the ratio being defined as uniformity of the second concentration in a central region within 60 mm from a center of the second main surface. The central region has an arithmetic mean roughness (Sa) of less than or equal to 0.5 nm.

### BRIEF DESCRIPTION OF DRAWINGS

FIG. 1 is a schematic plan view showing a configuration of a silicon carbide epitaxial substrate according to the present embodiment.

FIG. 2 is a schematic cross sectional view showing the configuration of the silicon carbide epitaxial substrate according to the present embodiment.

FIG. 3 is a schematic plan view showing measurement locations for carrier concentration.

FIG. 4 is a schematic plan view showing measurement locations for Sa and Ra.

FIG. 5 is a flowchart showing a method for manufacturing the silicon carbide epitaxial substrate according to the present embodiment.

FIG. 6 is a schematic view of a silicon carbide single crystal substrate.

FIG. 7 is a partial schematic cross sectional view showing a configuration of a film forming apparatus for performing the method for manufacturing the silicon carbide epitaxial substrate according to the present disclosure.

FIG. 8 shows an exemplary method for manufacturing a silicon carbide epitaxial substrate according to the present embodiment.

FIG. 9 shows an exemplary method for manufacturing a silicon carbide epitaxial substrate according to a comparative example.

FIG. 10 shows an exemplary concentration profile of nitrogen atoms in the silicon carbide epitaxial substrate according to the present embodiment as manufactured by the manufacturing method shown in FIG. 8.

FIG. 11 shows an exemplary concentration profile of nitrogen atoms in the silicon carbide epitaxial substrate according to the comparative example as manufactured by the manufacturing method shown in FIG. 9.

FIG. 12 shows an exemplary substrate holder for supporting a plurality of silicon carbide single crystal substrates.

FIG. 13 is a flowchart showing a method for manufacturing a silicon carbide semiconductor device according to the present embodiment.

FIG. 14 is a schematic cross sectional view showing a first step of the method for manufacturing the silicon carbide semiconductor device according to the present embodiment.

FIG. 15 is a schematic cross sectional view showing a second step of the method for manufacturing the silicon carbide semiconductor device according to the present embodiment.

FIG. 16 is a schematic cross sectional view showing a third step of the method for manufacturing the silicon carbide semiconductor device according to the present embodiment.

### DETAILED DESCRIPTION

[Overview of Embodiment of the Present Disclosure]

First, the following describes an overview of an embodiment of the present disclosure. Regarding crystallographic indications in the present specification, an individual orientation is represented by [], a group orientation is represented by <>, and an individual plane is represented by ( ) and a group plane is represented by {}. A crystallographically negative index is normally expressed by putting “−” (bar) above a numeral; however, in the present specification, the crystallographically negative index is expressed by putting a negative sign before the numeral.

(1) A silicon carbide epitaxial substrate 100 according to the present disclosure includes: a silicon carbide single crystal substrate 10 having a first main surface 11; a first silicon carbide layer 20 on silicon carbide single crystal substrate 10, first silicon carbide layer 20 having a first concentration of carriers; and a second silicon carbide layer 30 on first silicon carbide layer 20, second silicon carbide layer 30 having a second concentration of carriers smaller than the first concentration, second silicon carbide layer 30 including a second main surface 31 opposite to the first main surface. In a concentration profile of the carriers along a layering direction 104 in which first silicon carbide layer 20 and second silicon carbide layer 30 are layered, a transition region 34 in which the concentration of the carriers is changed between the first concentration and the second concentration has a width 105 of less than or equal to 1 μm. A ratio of a standard deviation of the second concentration to an average value of the second concentration is less than or equal to 5%, the ratio being defined as uniformity of the second concentration in a central region 5 within 60 mm from a center O of second main surface 31. The central region has an arithmetic mean roughness (Sa) of less than or equal to 0.5 nm.

A silicon carbide epitaxial substrate is used to manufacture a silicon carbide semiconductor device. The silicon carbide epitaxial substrate is required to achieve both improvement in in-plane uniformity of carrier concentration and reduction of surface roughness. In addition, the silicon carbide epitaxial substrate is required to have a steep change in carrier concentration at a boundary between the first silicon carbide layer and the second silicon carbide layer. According to the present disclosure, a silicon carbide epitaxial substrate can be realized which allows for improvement in in-plane uniformity of carrier concentration and reduction in surface roughness and which has a carrier concentration steeply changed in a transition region between the first silicon carbide layer and the second silicon carbide layer.

(2) In silicon carbide epitaxial substrate 100 according to (1), the width of transition region 34 is less than or equal to 0.5 μm.

(3) In silicon carbide epitaxial substrate 100 according to (1) or (2), the uniformity of the second concentration is less than or equal to 3%.

(4) In silicon carbide epitaxial substrate 100 according to any one of (1) to (3), the arithmetic mean roughness of central region 5 is less than or equal to 0.3 nm.

(5) In silicon carbide epitaxial substrate 100 according to any one of (1) to (4), the ratio of the standard deviation of the second concentration to the average value of the second concentration is less than or equal to 20% in a depth direction 103 of second silicon carbide layer 30 at any point in central region 5.

(6) A method for manufacturing a silicon carbide semiconductor device 300 according to the present disclosure includes: preparing silicon carbide epitaxial substrate 100 recited in any one of (1) to (5); and processing silicon carbide epitaxial substrate 100.

[Overview of Embodiment of the Present Disclosure]

Next, the following describes details of the embodiment of the present disclosure with reference to figures. In the description below, the same or corresponding elements are given the same reference characters and are not described repeatedly.

(Silicon Carbide Epitaxial Substrate)

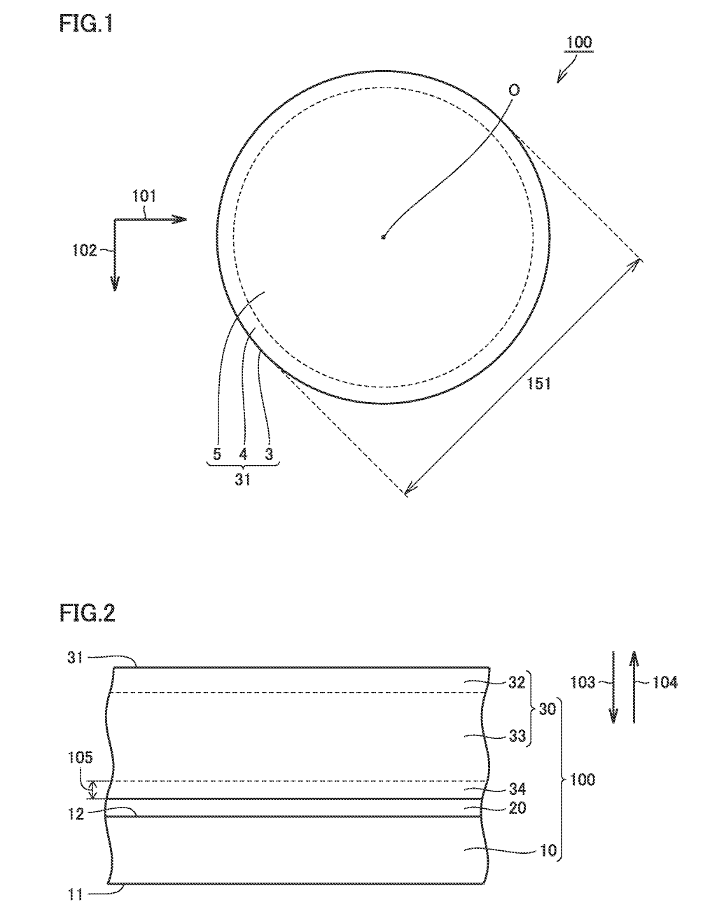

As shown in FIG. 1 and FIG. 2, silicon carbide epitaxial substrate 100 according to the present embodiment includes a silicon carbide single crystal substrate 10, a first silicon carbide layer 20, and a second silicon carbide layer 30. Silicon carbide single crystal substrate 10 has a first main surface 11. Second silicon carbide layer 30 has a second main surface 31. Second main surface 31 is located opposite to first main surface 11.

Silicon carbide epitaxial substrate 100 may have at least one of a first flat extending in a first direction 101 and a second flat extending in a second direction 102. First direction 101 is a <11-20> direction, for example. Second direction 102 is a <1-100> direction, for example.

Second main surface 31 has a maximum diameter 151 (diameter) of more than or equal to 150 mm, for example. Maximum diameter 151 may be more than or equal to 200 mm, or may be more than or equal to 250 mm. The upper limit of maximum diameter 151 is not limited in particular. The upper limit of maximum diameter 151 may be 300 mm, for example.

Second main surface 31 includes an outer circumferential region 4, a central region 5 surrounded by outer circumferential region 4, and an outer edge 3. Central region 5 is a region having a distance within 60 mm from a center O of second main surface 31.

Silicon carbide single crystal substrate 10 is constituted of a silicon carbide single crystal. The silicon carbide single crystal has a polytype of 4 H—SiC, for example. 4 H—SiC is superior to other polytypes in terms of electron mobility, dielectric strength, and the like. Silicon carbide single crystal substrate 10 includes nitrogen (N) as an n type impurity. The conductivity type of silicon carbide single crystal substrate 10 is n type.

Silicon carbide single crystal substrate 10 includes a third main surface 12 opposite to first main surface 11. Third main surface 12 corresponds to a {0001} plane or a plane inclined by less than or equal to 8° relative to the {0001} plane, for example. When third main surface 12 is inclined relative to the {0001} plane, the normal line of third main surface 12 is inclined in the <11-20> direction, for example.

First silicon carbide layer 20 is an epitaxial layer formed on silicon carbide single crystal substrate 10. First silicon carbide layer 20 is located on third main surface 12. Second silicon carbide layer 30 is an epitaxial layer formed on first silicon carbide layer 20.

The conductivity type of each of first silicon carbide layer 20 and second silicon carbide layer 30 is n type. Each of first silicon carbide layer 20 and second silicon carbide layer 30 includes nitrogen atoms as an n type impurity.

The carrier concentration in first silicon carbide layer 20 may be lower than the carrier concentration in silicon carbide single crystal substrate 10. The carrier concentration in second silicon carbide layer 30 is lower than the carrier concentration in first silicon carbide layer 20.

For example, the carrier concentration in silicon carbide single crystal substrate 10 is about 1×10¹⁹ cm⁻³. The carrier concentration in first silicon carbide layer 20 is about 1×10¹⁷ to 1×10¹⁹ cm⁻³. The carrier concentration in second silicon carbide layer 30 is less than or equal to 1×10 ¹⁶ cm⁻³, for example.

In the description below, a direction perpendicular to second main surface 31 and extending from second main surface 31 toward third main surface 12 will be referred to as “depth direction”. On the other hand, the term “layering direction” refers to a direction opposite to the “depth direction”, i.e., a direction in which first silicon carbide layer 20 and second silicon carbide layer 30 are layered in this order. In FIG. 2, a depth direction 103 and a layering direction 104 are indicated by arrows.

A transition region 34 exists between first silicon carbide layer 20 and second silicon carbide layer 30. Transition region 34 is defined as a region in which the carrier concentration is changed from a first concentration to a second concentration along the layering direction. Width 105 of transition region 34 can be defined as the length of transition region 34 in the layering direction. Width 105 is less than or equal to 1 μm, and is preferably less than or equal to 0.5 μm.

(In-Plane Uniformity of Carrier Concentration)

In-plane uniformity of the carrier concentration in central region 5 is less than or equal to 5%. The in-plane uniformity is a ratio (σ/ave) of a standard deviation of the carrier concentration of the carrier concentration of second silicon carbide layer 30 to an average value of the carrier concentration of second silicon carbide layer 30 in a direction parallel to second main surface 31. The in-plane uniformity of the carrier concentration is preferably less than or equal to 3%.

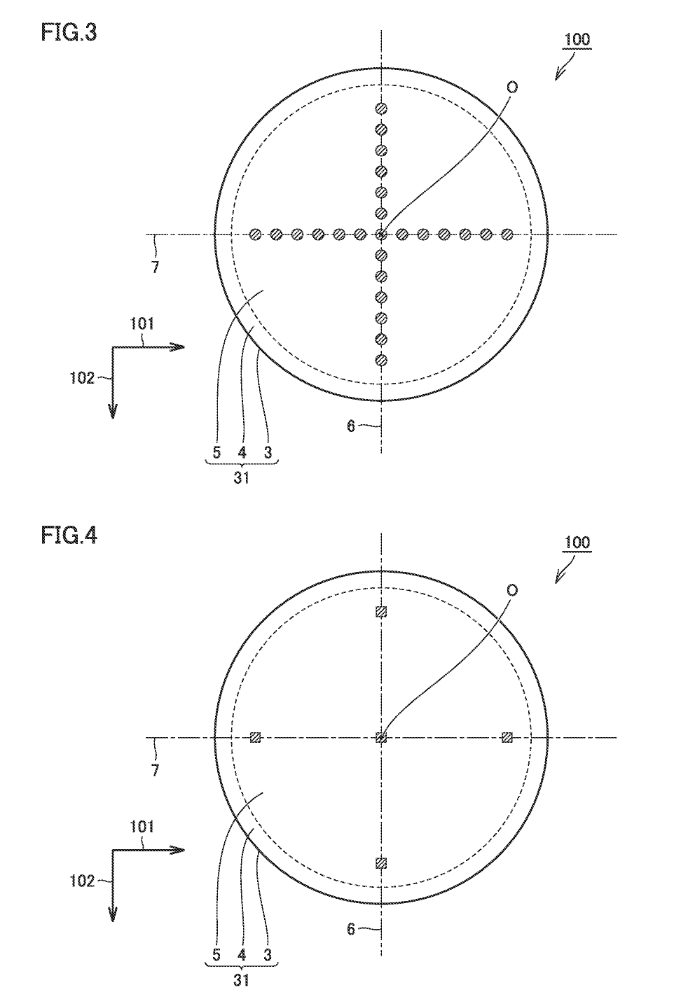

The carrier concentration in central region 5 is measured using a C-V measuring apparatus employing a mercury probe method, for example. The area of the probe is 0.01 cm², for example. As shown in FIG. 3, the measurement is performed at measurement locations obtained by substantially equally dividing, into 12, a second line segment 7 extending through center O and parallel to first direction 101, for example. Likewise, the measurement is performed at measurement locations obtained by substantially equally dividing, into 12, a first line segment 6 extending through center O and parallel to second direction 102. Center O serves as one measurement location. The carrier concentration is measured at the total of 25 measurement locations (regions indicated by hatching) in central region 5. Based on the result of measurement at the total of 25 measurement locations, the average value and standard deviation of the carrier concentration are calculated.

As shown in FIG. 2, second silicon carbide layer 30 includes a surface layer region 32 and an underlying layer region 33. Surface layer region 32 is a region within 10 μm from second main surface 31 toward third main surface 12 in the direction perpendicular to second main surface 31. A measurement depth is adjusted in accordance with applied voltage. Underlying layer region 33 is a region interposed between surface layer region 32 and first silicon carbide layer 20.

The carrier concentration is measured at surface layer region 32. Measurement data is plotted with the vertical axis representing 1/C² and the horizontal axis representing V. Based on inclination of a straight line of the measurement data, the carrier concentration is estimated.

(Arithmetic Mean Roughness: Ra)

Central region 5 has an arithmetic mean roughness (Ra) of less than or equal to 1 nm. The arithmetic mean roughness (Ra) can be measured by an AFM (Atomic Force Microscope), for example. A measurement range for the arithmetic mean roughness (Ra) is a square region of 5 μm×5 μm, for example. The arithmetic mean roughness (Ra) of central region 5 is preferably less than or equal to 0.3 nm, and is more preferably less than or equal to 0.2 nm.

As shown in FIG. 4, it is assumed that in central region 5, there are first line segment 6 extending through center O of second main surface 31 and parallel to first direction 101, and second line segment 7 extending through center O of second main surface 31 and parallel to second direction 102, for example. Arithmetic mean roughness Ra is measured at the following regions: square regions including points located on first line segment 6 and separated from center O by a certain distance leftward and rightward; square regions including points located on second line segment 7 and separated from center O by a certain distance upward and downward; and a square region including center O. For example, arithmetic mean roughness Ra is measured at the following regions: the square regions located at both sides to sandwich center O on first line segment 6; the square regions located at both sides to sandwich center O on second line segment 7; and the square region including center O (i.e., a total of five measurement regions indicated by hatching in FIG. 4).

(Arithmetic Mean Roughness: Sa)

An arithmetic mean roughness (Sa) of central region 5 is less than or equal to 1 nm. The arithmetic mean roughness (Sa) is a parameter obtained by extending the two-dimensional arithmetic mean roughness (Ra) to three dimensions. The arithmetic mean roughness (Sa) can be measured using a white light interferometric microscope, for example. As the white light interferometric microscope, BW-D507 provided by NIKON can be used, for example. A measurement range for the arithmetic mean roughness (Sa) is a square region of 255 μm×255 μm, for example. The arithmetic mean roughness (Sa) of central region 5 is preferably less than or equal to 0.5 nm, and is more preferably less than or equal to 0.3 nm. For example, in five square regions shown in FIG. 4, arithmetic mean roughness Sa is measured.

(Width of Transition Region)

For example, the carrier concentration along depth direction 103 of silicon carbide epitaxial substrate 100 can be measured by measuring a nitrogen concentration using a SIMS (Secondary Ion Mass Spectrometry). As the SIMS, IMS7f provided by Cameca can be used, for example. For example, the following measurement conditions can be used: O2⁺ is employed as a primary ion; and a primary ion energy of 8 keV is employed. It should be noted that the nitrogen concentration is determined in the measurement using the SIMS. The carrier concentration is determined by subtracting the concentration of a p type impurity serving as a compensation impurity from the nitrogen concentration; however, the concentration of the p type impurity is reduced to a substantially negligible amount and therefore the nitrogen concentration is assumed as the carrier concentration.

The nitrogen concentration of each of first silicon carbide layer 20 and second silicon carbide layer 30 can be determined as follows. In each of the layers, the nitrogen concentration is measured to a depth of at least 0.1 μm. A plurality of values obtained by the measurement are averaged. Accordingly, the nitrogen concentration of each layer is determined. A process such as smoothing or interpolation may be performed onto the result of measurement in order to determine the nitrogen concentration.

(Method for Manufacturing Silicon Carbide Epitaxial Substrate)

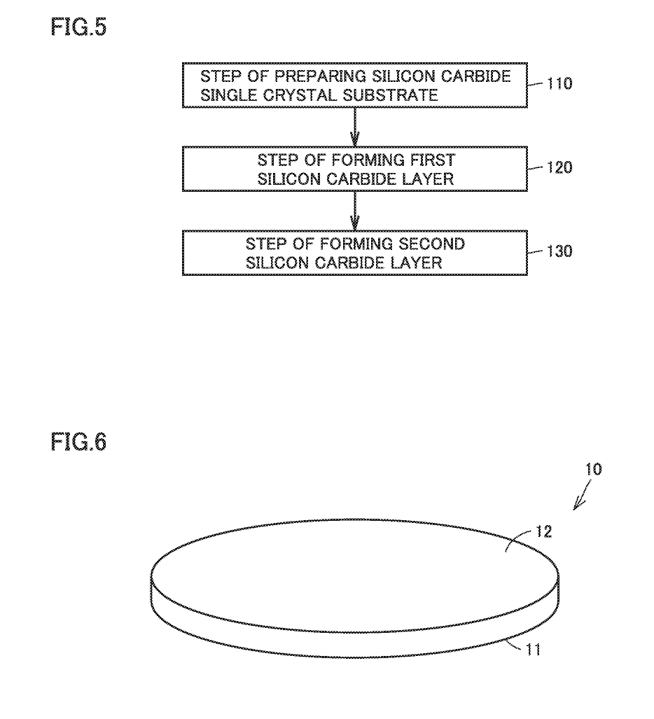

FIG. 5 is a flowchart showing a method for manufacturing the silicon carbide epitaxial substrate according to the present embodiment. As shown in FIG. 5, a step (110) of preparing a silicon carbide single crystal substrate is performed first. Silicon carbide single crystal substrate 10 is composed of a hexagonal silicon carbide having a polytype of 4H, for example. As shown in FIG. 6, silicon carbide single crystal substrate 10 having first main surface 11 and third main surface 12 is prepared. Silicon carbide single crystal substrate 10 is prepared by slicing an ingot composed of a silicon carbide single crystal manufactured by a sublimation method, for example.

Third main surface 12 corresponds to a plane inclined by an off angle relative to a basal plane. The basal plane is, for example, the {0001} plane, and is particularly a (0001) Si plane. The off angle is more than or equal to 2° and less than or equal to 8°, for example. The off direction may be the <1-100> direction or may be the <11-20> direction.

Next, silicon carbide single crystal substrate 10 is placed in a film forming apparatus. In the film forming apparatus, a step (120) of forming first silicon carbide layer 20 is performed. Then, a step (130) of forming second silicon carbide layer 30 is performed in the film forming apparatus.

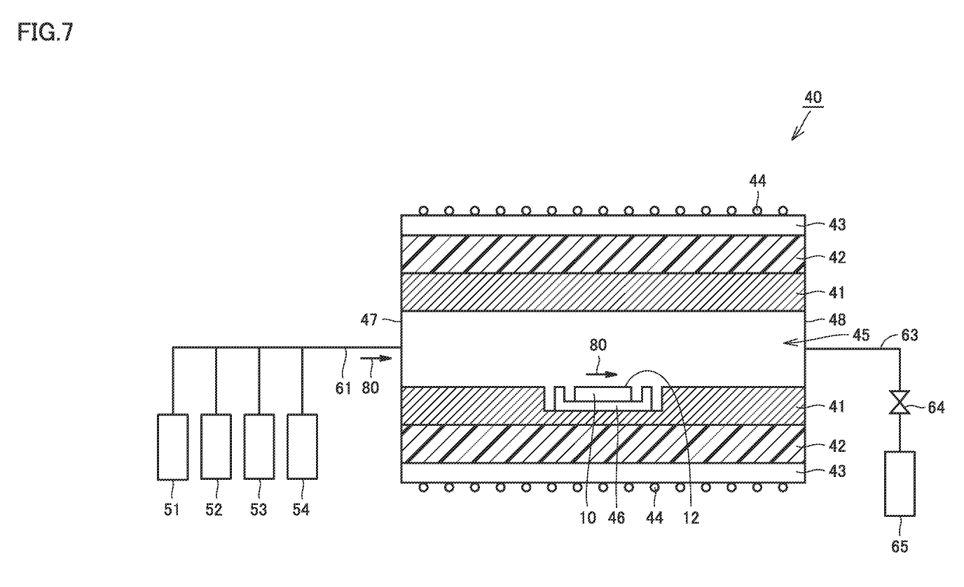

FIG. 7 is a partial schematic cross sectional view showing a configuration of film forming apparatus 40 for performing the method for manufacturing the silicon carbide epitaxial substrate according to the present disclosure. Film forming apparatus 40 is a CVD (Chemical Vapor Deposition) apparatus, for example. As shown in FIG. 7, film forming apparatus 40 mainly includes a heating element 41, a heat insulator 42, a quartz tube 43, an induction heating coil 44, a substrate holder 46, gas supply sources 51 to 54, tubes 61, 63, a valve 64, and an exhaust pump 65.

Heating element 41 has a hollow structure and a reaction chamber 45 is formed therein. Heat insulating member 42 is disposed to surround the outer circumference of heating element 41. Quartz tube 43 is disposed to surround the outer circumference of heat insulator 42. Induction heating coil 44 is provided to be wound around the outer circumference of quartz tube 43. Heating element 41, heat insulator 42, and induction heating coil 44 are elements of a heating structure for heating reaction chamber 45.

Substrate holder 46 is placed in reaction chamber 45. Substrate holder 46 has a recess for holding silicon carbide single crystal substrate 10 therein. Silicon carbide single crystal substrate 10 is placed at the recess of substrate holder 46 to expose third main surface 12 at substrate holder 46. As one example, substrate holder 46 is a susceptor.

Gas supply source 51 supplies hydrogen (H₂) gas as a carrier gas. Each of gas supply sources 52, 53 supplies a source material gas. In the present disclosure, gas supply source 52 supplies silane (SiH₄) gas, and gas supply source 53 supplies propane (C₃H₈) gas. Gas supply source 52 may supply a gas including silicon atoms, other than silane. Other examples of the gas including the silicon atoms include silicon tetrachloride (SiCl₄) gas, trichlorosilane (SiHCl₃) gas, and dichlorosilane (SiH₂Cl₂) gas.

Gas supply source 54 supplies ammonia (NH₃) gas as a dopant gas. By using the ammonia gas, it can be expected to improve both the in-plane uniformity of the carrier concentration of the silicon carbide epitaxial substrate and in-plane flatness thereof.

The ammonia gas is heated in reaction chamber 45. A preheating structure for heating the ammonia gas before introducing the ammonia gas into reaction chamber 45 may be provided.

Tube 61 is configured to introduce, into a gas inlet 47, mixed gas 80 including the carrier gas, source material gas, and ammonia gas. Tube 63 is configured to be connected to gas outlet 48 and exhaust the gas from reaction chamber 45. Exhaust pump 65 is connected to tube 63. Valve 64 is provided at tube 63.

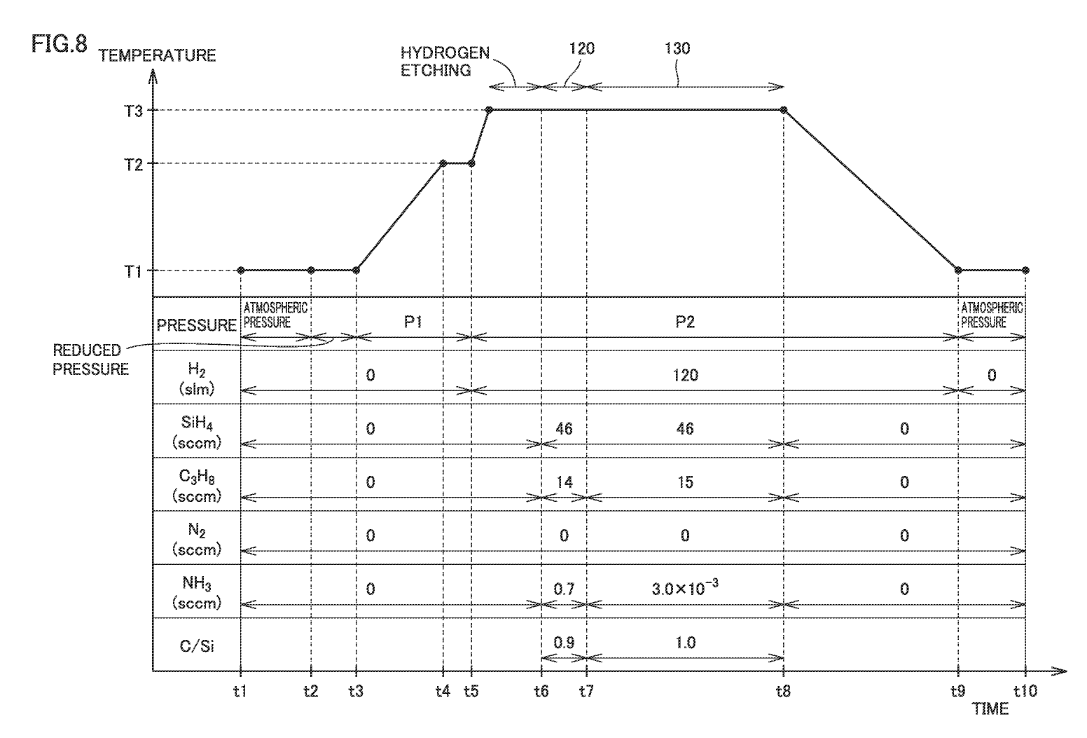

The following describes details of a series of processes including step 120 and step 130 and performed by film forming apparatus 40. As shown in FIG. 7 and FIG. 8, at a time t1, silicon carbide single crystal substrate 10 is placed on substrate holder 46. At time t1, a temperature in reaction chamber 45 is T1 and a pressure in reaction chamber 45 is an atmospheric pressure, for example. Temperature T1 is a room temperature, for example.

At a time t2, the pressure starts to be reduced in reaction chamber 45. At a time t3, the pressure in reaction chamber 45 reaches a pressure P1. Pressure P1 is about 1×10⁻⁶ Pa, for example.

At a time t3, the temperature of reaction chamber 45 starts to be increased. Heating element 41 is inductively heated through an electromagnetic induction effect by supplying high-frequency current to induction heating coil 44. Accordingly, substrate holder 46 and silicon carbide single crystal substrate 10 are heated.

During a period of a time t4 to a time t5, the temperature in reaction chamber 45 is held at a temperature T2. Temperature T2 is 1100° C., for example. The holding time (period of time t4 to time t5) is 10 minutes, for example. By setting the holding time, it is expected that a temperature difference between substrate holder 46 and silicon carbide single crystal substrate 10 becomes small. Therefore, it is expected that a temperature distribution in the plane of silicon carbide single crystal substrate 10 becomes uniform.

At time t5, the temperature of reaction chamber 45 is resumed to be increased. In the present disclosure, from time t5, hydrogen (H₂) gas is introduced into reaction chamber 45. The flow rate of the hydrogen gas is about 120 slm, for example. The unit “slm” for the flow rate represents “L/min” in a standard state (0° C.; 101.3 kPa). With this operation, it is expected to reduce nitrogen remaining in reaction chamber 45, for example. Further, third main surface 12 of silicon carbide single crystal substrate 10 is etched by the hydrogen. By the introduction of the hydrogen gas, the pressure in reaction chamber 45 is changed from pressure P1 to a pressure P2. Pressure P2 is 80 mbar (8 kPa), for example.

After the temperature of reaction chamber 45 reaches a temperature T3, the temperature of reaction chamber 45 is maintained at temperature T3 for a certain time. Temperature T3 is 1630° C., for example. Temperature T3 is a growth temperature at which epitaxial growth proceeds.

A process from a time t6 to a time t7 corresponds to the process of step 120. From time t6, the source material gas (silane gas and propane) and the doping gas (ammonia gas) are introduced into reaction chamber 45.

It should be noted that no nitrogen gas (N₂ gas) is used for the dopant gas in the present disclosure. Accordingly, in FIG. 8, the flow rate of the nitrogen gas is indicated as 0 sccm. The flow rate of the nitrogen gas (N₂ gas) is illustrated in FIG. 8 for the purpose of comparison with that in a below-described manufacturing method.

First silicon carbide layer 20 is formed on silicon carbide single crystal substrate 10 through epitaxial growth. For example, the carrier concentration of first silicon carbide layer 20 is 1×10¹⁸ cm⁻³. During the period of time t6 to time t7, the flow rate of the hydrogen gas is 120 slm, the flow rate of the silane gas is 46 sccm, the flow rate of the propane gas is 14 sccm, and the flow rate of the ammonia gas is 0.7 sccm. A volume ratio (N/SiH₄) of the silane gas to the ammonia gas is 0.015.

A C/Si ratio in the source material gas is 0.9, for example. The thickness of first silicon carbide layer 20 is 1 μm, for example. The period of time t6 to time t7 is 3 minutes, for example. During the formation of first silicon carbide layer 20 by the epitaxial growth, substrate holder 46 is rotated.

A process from time t7 to a time t8 corresponds to the process of step 130. In step 130, second silicon carbide layer 30 is formed on first silicon carbide layer 20 by the epitaxial growth. During the period of time t7 to time t8, the flow rate of the hydrogen gas is 120 slm, the flow rate of the silane gas is 46 sccm, the flow rate of the propane gas is 15 sccm, and the flow rate of the ammonia gas is 3.0×10⁻³ sccm. A C/Si ratio in the source material gas is 1.0, for example. The thickness of second silicon carbide layer 30 is 15 μm, for example. The period of time t7 to time t8 is 31 minutes, for example. During the formation of second silicon carbide layer 30 by the epitaxial growth, substrate holder 46 is rotated.

Preferably, in steps 120, 130, the temperature of silicon carbide single crystal substrate 10 in the in-plane direction is maintained uniformly. Specifically, during the period of time t6 to time t8, a difference between the maximum temperature and the minimum temperature is maintained to be less than or equal to 10° C. in third main surface 12 of silicon carbide single crystal substrate 10.

In at least one of steps 120, 130, a chlorine-based gas (for example, HCl gas) may be mixed in mixed gas 80. By introducing the chlorine-based gas into reaction chamber 45, it can be expected to increase the growth rate of the silicon carbide layer.

At time t8, the supply of the silane gas, the propane gas, and the ammonia gas is stopped, thereby ending step 130. Thereafter, a cooling step is performed. For example, during a period of time t8 to a time t9, the temperature of silicon carbide epitaxial substrate 100 is decreased from temperature T3 to temperature T1. The period of time t8 to time t9 is 60 minutes, for example. Temperature T3 is 1600° C., for example. A cooling rate of silicon carbide epitaxial substrate 100 is (1600−100)° C./1 hour=1500° C./hour, for example. The cooling rate in the cooling step may be less than or equal to 1500° C./hour, may be less than or equal to 1300° C./hour, or may be less than or equal to 1000° C./hour.

During a period of time t9 to a time t10, the pressure in reaction chamber 45 is maintained at the atmospheric pressure, and the temperature in reaction chamber 45 is maintained at the room temperature. After the temperature of silicon carbide epitaxial substrate 100 is around the room temperature, silicon carbide epitaxial substrate 100 is removed from reaction chamber 45. Through the manufacturing method described above, silicon carbide epitaxial substrate 100 is completed.

It should be noted that the pressure in reaction chamber 45 may be reduced in the cooling step. The pressure in reaction chamber 45 may be reduced from 100 mbar (10 kPa) to 10 mbar (1 kPa) in about 10 minutes, for example.

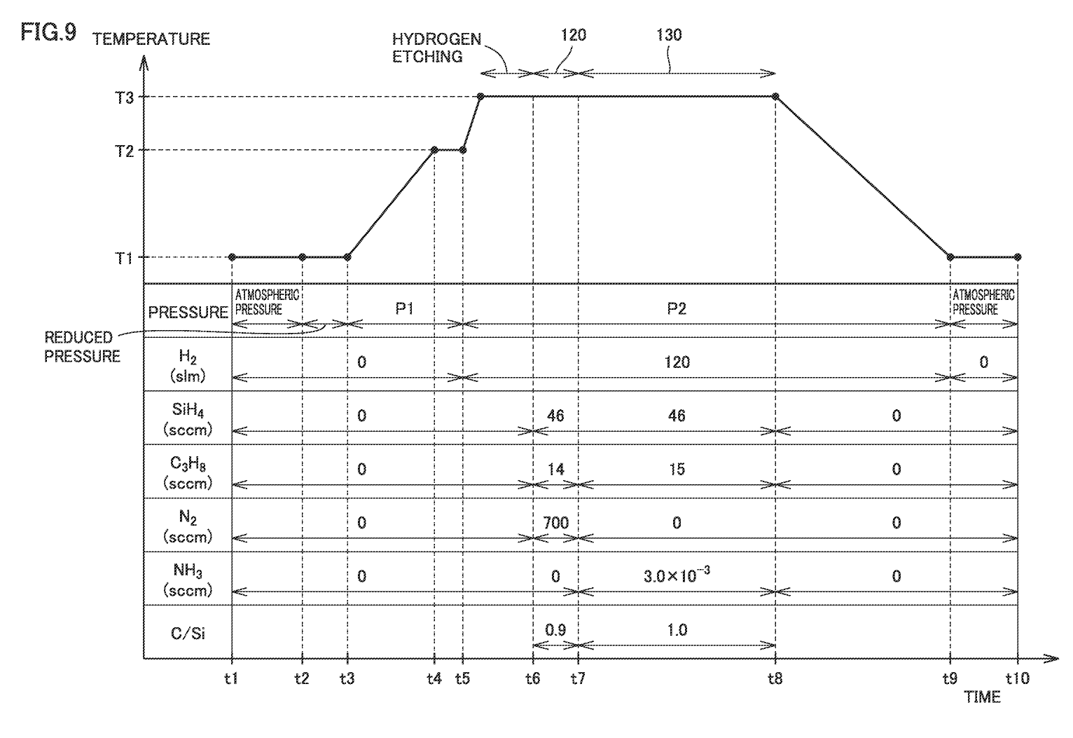

A nitrogen gas can be used as the dopant gas for forming the n type silicon carbide layer. A comparative example to the manufacturing method shown in FIG. 8 is shown in FIG. 9. According to the manufacturing method shown in FIG. 9, in step 120, nitrogen gas is used as the dopant gas instead of the ammonia gas. The flow rate of the nitrogen gas is 700 sccm, for example. The other conditions are the same as the conditions shown in FIG. 8, and will not be therefore described repeatedly.

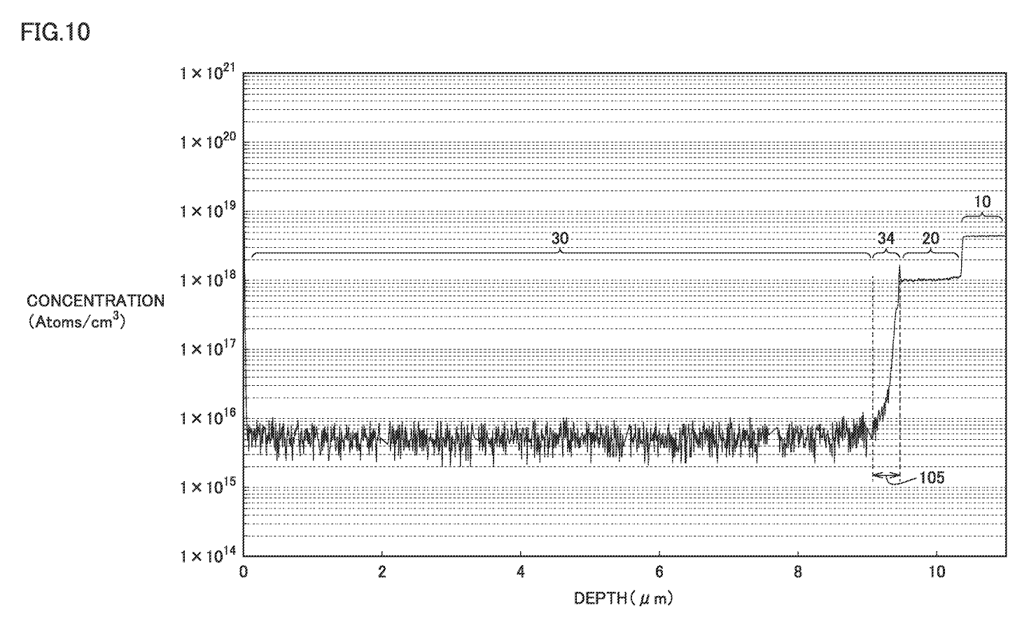

FIG. 10 shows an exemplary concentration profile of nitrogen atoms in the silicon carbide epitaxial substrate according to the present embodiment as manufactured by the manufacturing method shown in FIG. 8. In the example shown in FIG. 10, width 105 of transition region 34 is about 0.5 μm. In depth direction 103 of second silicon carbide layer 30, the ratio of the standard deviation of the nitrogen concentration to the average value of the nitrogen concentration is less than or equal to 20%.

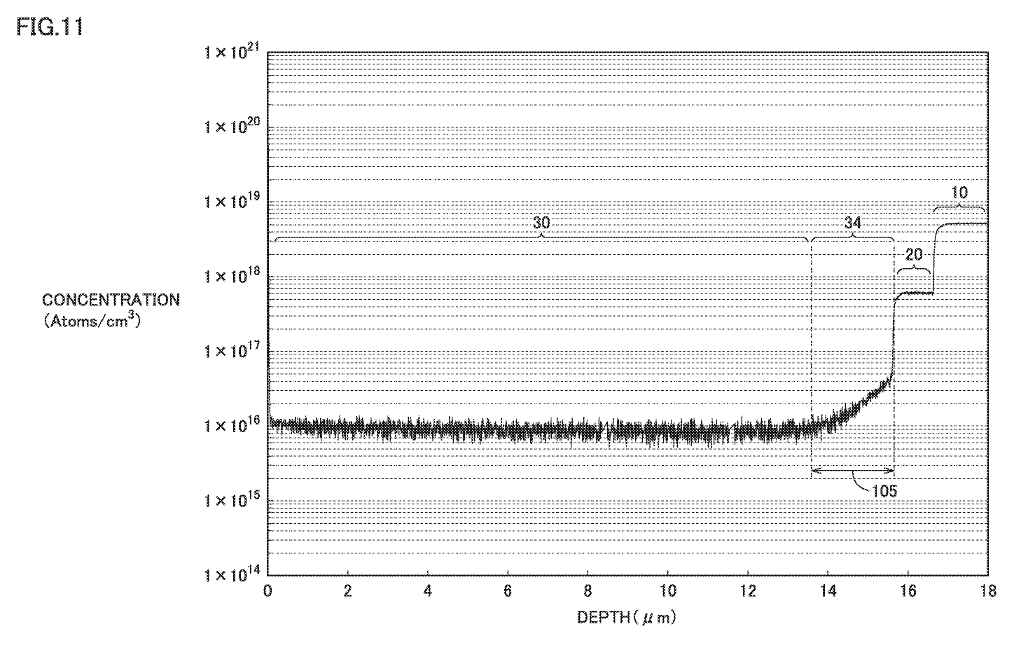

FIG. 11 shows an exemplary concentration profile of nitrogen atoms in the silicon carbide epitaxial substrate according to the comparative example as manufactured by the manufacturing method shown in FIG. 9. In the example shown in FIG. 11, width 105 of transition region 34 is about 2.0 μm.

According to the present disclosure, the silicon carbide layer is epitaxially grown with the low C/Si ratio. Accordingly, it can be expected to suppress step-bunching. Therefore, it can be expected to improve the flatness of second main surface 31 of silicon carbide epitaxial substrate 100.

On the other hand, when the C/Si ratio is low, the nitrogen atoms are likely to be included in the silicon carbide layer due to a site competition effect. When the nitrogen atoms remain in reaction chamber 45, the nitrogen atoms may be presumably included in the silicon carbide layer that is being grown.

When the nitrogen gas is used for the dopant gas, the nitrogen atoms are likely to remain in reaction chamber 45. This is because the temperature for sufficiently thermally decomposing the nitrogen gas is likely to be higher than the temperature for thermally decomposing the ammonia gas. When the dopant gas is nitrogen gas in the formation of first silicon carbide layer 20, the nitrogen atoms remaining in reaction chamber 45 may be included in second silicon carbide layer 30 during the growth of second silicon carbide layer 30.

Second silicon carbide layer 30 is formed such that the carrier concentration of second silicon carbide layer 30 becomes lower than the carrier concentration of first silicon carbide layer 20. It is desirable that the carrier concentration is changed steeply between first silicon carbide layer 20 and second silicon carbide layer 30. However, since the nitrogen atoms remaining in reaction chamber 45 are included in second silicon carbide layer 30, the change of the carrier concentration from the first concentration to the second concentration becomes gradual as shown in FIG. 11. Therefore, width 105 of transition region 34 is large. As width 105 of transition region 34 is larger, the substantial thickness of second silicon carbide layer 30 is decreased.

As shown in FIG. 10, according to the present disclosure, the ammonia gas is used for the dopant gas in each of steps 120, 130. Since the ammonia gas is sufficiently thermally decomposed in step 120, a larger amount of nitrogen atoms are included in the silicon carbide layer and an amount of the nitrogen atoms remaining in reaction chamber 45 can be reduced. Therefore, according to the present embodiment, the change of the carrier concentration at an interface between first silicon carbide layer 20 and second silicon carbide layer 30 becomes steep. In other words, width 105 of transition region 34 can be small.

According to the concentration profile shown in FIG. 10, in transition region 34, the nitrogen concentration is changed substantially monotonously. However, silicon carbide epitaxial substrate 100 according to the present embodiment is not thus limited. For example, in transition region 34, the nitrogen concentration may be changed stepwisely.

In the manufacturing method according to the present disclosure, a step of vacuuming the inside of reaction chamber 45 using exhaust pump 65 may be added between step 120 and step 130. It can be expected to further reduce the amount of the nitrogen atoms remaining in reaction chamber 45 when starting the formation of second silicon carbide layer 30. Therefore, it can be expected that the change of the nitrogen concentration at the interface between first silicon carbide layer 20 and second silicon carbide layer 30 becomes steeper.

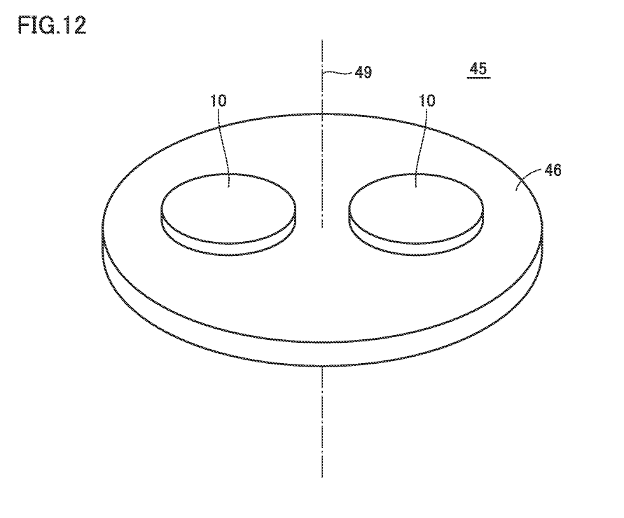

In the manufacturing method according to the present disclosure, a plurality of silicon carbide single crystal substrates may be placed in reaction chamber 45. As shown in FIG. 12, two silicon carbide single crystal substrates 10 may be placed on substrate holder 46, for example. In reaction chamber 45, substrate holder 46 may be rotated around a center axis 49 as a center.

(Method for Manufacturing Silicon Carbide Semiconductor Device)

The following describes a method of manufacturing a silicon carbide semiconductor device 300 according to the present embodiment.

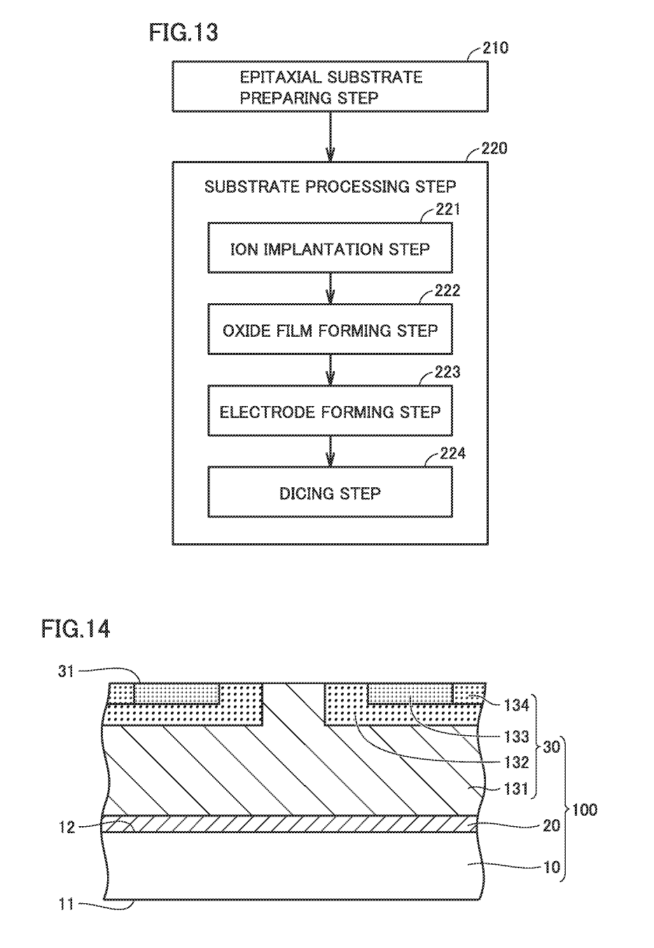

As shown in FIG. 13, the method for manufacturing the silicon carbide semiconductor device according to the present embodiment mainly includes an epitaxial substrate preparing step (210) and a substrate processing step (220).

First, the epitaxial substrate preparing step (210) is performed. Specifically, the silicon carbide epitaxial substrate is prepared by the above-described method for manufacturing the silicon carbide epitaxial substrate.

Next, the substrate processing step (220) is performed. Specifically, the silicon carbide epitaxial substrate is processed to manufacture a silicon carbide semiconductor device. The term “process” encompasses various processes such as ion implantation, heat treatment, etching, oxide film formation, electrode formation, dicing, and the like. That is, the substrate processing step may include at least one of the ion implantation, the heat treatment, the etching, the oxide film formation, the electrode formation, and the dicing.

The following describes a method for manufacturing a MOSFET (Metal Oxide Semiconductor Field Effect Transistor) serving as an exemplary silicon carbide semiconductor device. The substrate processing step (220) includes an ion implantation step (221), an oxide film forming step (222), an electrode forming step (223), and a dicing step (224).

First, the ion implantation step (221: FIG. 13) is performed. For example, a p type impurity such as aluminum (Al) is implanted into second main surface 31 on which a mask (not shown) provided with an opening is formed. Accordingly, as shown in FIG. 14, a body region 132 having p type conductivity is formed. Next, an n type impurity such as phosphorus (P) is implanted into body region 132 at a predetermined location, for example. Accordingly, a source region 133 having n type conductivity is formed. Next, a p type impurity such as aluminum is implanted into source region 133 at a predetermined location. Accordingly, contact region 134 having p type conductivity is formed.

A portion of second silicon carbide layer 30 other than body region 132, source region 133, and contact region 134 serves as a drift region 131. Source region 133 is separated from drift region 131 by body region 132. The ion implantation may be performed while heating silicon carbide epitaxial substrate 100 at about more than or equal to 300° C. and less than or equal to 600° C. After the ion implantation, activation annealing is performed to silicon carbide epitaxial substrate 100. By the activation annealing, the impurities implanted in second silicon carbide layer 30 are activated, thereby generating carriers in each region. An atmosphere for the activation annealing may be an argon (Ar) atmosphere, for example. The temperature of the activation annealing may be about 1800° C., for example. The activation annealing may be performed for about 30 minutes, for example.

Next, an oxide film forming step (222: FIG. 13) is performed. For example, by heating silicon carbide epitaxial substrate 100 in an atmosphere including oxygen, an oxide film 136 is formed on second main surface 31 (see FIG. 15). Oxide film 136 is composed of silicon dioxide (SiO₂) or the like, for example. Oxide film 136 functions as a gate insulating film. The temperature of the thermal oxidation process may be about 1300° C., for example. The thermal oxidation process is performed for about 30 minutes, for example.

After oxide film 136 is formed, a heat treatment may be further performed in a nitrogen atmosphere. For example, the heat treatment may be performed at about 1100° C. for about 1 hour in an atmosphere of nitrogen monoxide (NO), nitrous oxide (N₂O), or the like. Further, a heat treatment may be then performed in an argon atmosphere. For example, the heat treatment may be performed at about 1100 to 1500° C. in the argon atmosphere for about 1 hour.

Next, the electrode forming step (223: FIG. 13) is performed. First electrode 141 is formed on oxide film 136. First electrode 141 functions as a gate electrode. First electrode 141 is formed by the CVD method, for example. First electrode 141 is composed of a conductive polysilicon containing an impurity, for example. First electrode 141 is formed at a location facing source region 133 and body region 132.

Next, an interlayer insulating film 137 is formed to cover first electrode 141. Interlayer insulating film 137 is formed by the CVD method, for example. Interlayer insulating film 137 is composed of silicon dioxide or the like, for example. Interlayer insulating film 137 is formed in contact with first electrode 141 and oxide film 136. Next, oxide film 136 and interlayer insulating film 137 at a predetermined location are removed by etching. Accordingly, source region 133 and contact region 134 are exposed through oxide film 136.

For example, second electrode 142 is formed at the exposed portion by a sputtering method. Second electrode 142 functions as a source electrode. Second electrode 142 is composed of titanium, aluminum, silicon, and the like, for example. After second electrode 142 is formed, second electrode 142 and silicon carbide epitaxial substrate 100 are heated at a temperature of about 900 to 1100° C., for example. Accordingly, second electrode 142 and silicon carbide epitaxial substrate 100 are brought into ohmic contact with each other. Next, an interconnection layer 138 is formed in contact with second electrode 142. Interconnection layer 138 is composed of a material including aluminum, for example.

Next, a passivation protecting film (not shown) is formed on interconnection layer 138 by plasma CVD, for example. The passivation protecting film includes a SiN film, for example. In order to connect a bonding wire, a portion of the passivation protecting film is etched to interconnection layer 138, thus forming an opening in the passivation protecting film. Next, back grinding is performed to first main surface 11 of silicon carbide single crystal substrate 10. Accordingly, silicon carbide single crystal substrate 10 is made thin. Next, a third electrode 143 is formed on first main surface 11. Third electrode 143 functions as a drain electrode. Third electrode 143 is composed of an alloy (for example, NiSi or the like) including nickel and silicon, for example.

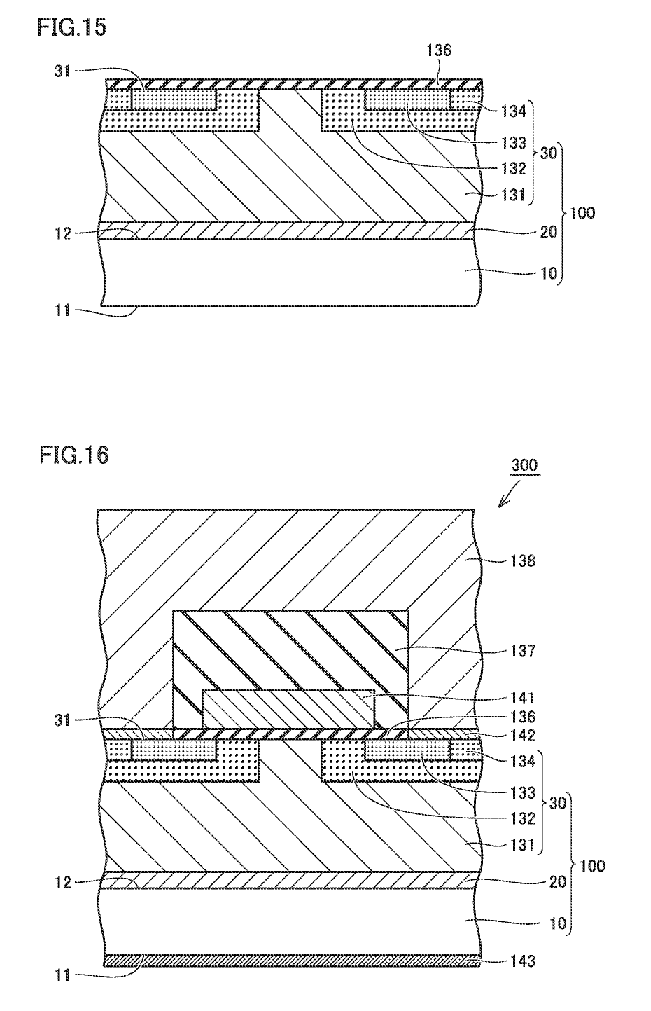

Next, the dicing step (224: FIG. 13) is performed. For example, silicon carbide epitaxial substrate 100 is diced along a dicing line, thereby dividing silicon carbide epitaxial substrate 100 into a plurality of semiconductor chips. In this way, a silicon carbide semiconductor device 300 is manufactured (see FIG. 16).

In the description above, the method for manufacturing the MOSFET exemplarily serving as the silicon carbide semiconductor device according to the present disclosure has been described; however, the manufacturing method according to the present disclosure is not limited to this. The manufacturing method according to the present disclosure is applicable to various silicon carbide semiconductor devices such as an IGBT (Insulated Gate Bipolar Transistor), an SBD (Schottky Barrier Diode), a thyristor, a GTO (Gate Turn Off thyristor), and a PiN diode.

When the width of transition region 34 is thick, the breakdown voltage of the silicon carbide semiconductor device may be decreased, for example. When the silicon carbide semiconductor device is a MOSFET, the low breakdown voltage presumably leads to decreased reliability of the gate insulating film. According to the present embodiment, the silicon carbide semiconductor device is manufactured using silicon carbide epitaxial substrate 100 including transition region 34 having a small width 105 (less than or equal to 1 μm). Therefore, it can be expected to suppress the above-mentioned problem.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

3: outer edge; 4: outer circumferential region; 5: central region; 6: first line segment; 7: second line segment; 10: single crystal substrate; 11: first main surface; 12: third main surface; 20: first silicon carbide layer; 30: second silicon carbide layer; 31: second main surface; 32: surface layer region; 33: underlying layer region; 34: transition region; 40: film forming apparatus; 41: heating element; 42: heat insulator; 43: quartz tube; 44: induction heating coil; 45: reaction chamber; 46: substrate holder; 47: gas inlet; 48: gas outlet; 49: center axis; 51, 52, 53, 54: gas supply source; 61, 63: tube; 64: valve; 65: exhaust pump; 80: mixed gas; 100: silicon carbide epitaxial substrate; 101: first direction; 102: second direction; 103: depth direction; 104: layering direction; 105: width; 120, 130, 210, 220 to 224: step; 131: drift region; 132: body region; 133: source region; 134: contact region; 136: oxide film; 137: interlayer insulating film; 138: interconnection layer; 141: first electrode; 142: second electrode; 143: third electrode; 151: maximum diameter; 300: silicon carbide semiconductor device; O: center; P1, P2: pressure; Ra, Sa: arithmetic mean roughness; T1, T2, T3: temperature; t1, t2, t3, t4, t5, t6, t7, t8, t9, t10: time.

1. A silicon carbide epitaxial substrate comprising:
a silicon carbide single crystal substrate having a first main surface;
a first silicon carbide layer on the silicon carbide single crystal substrate, the first silicon carbide layer having a first concentration of carriers; and
a second silicon carbide layer on the first silicon carbide layer, the second silicon carbide layer having a second concentration of carriers smaller than the first concentration, the second silicon carbide layer including a second main surface opposite to the first main surface,
in a concentration profile of the carriers along a layering direction in which the first silicon carbide layer and the second silicon carbide layer are layered, a transition region in which the concentration of the carriers is changed between the first concentration and the second concentration having a width of less than or equal to 1 μm,
a ratio of a standard deviation of the second concentration to an average value of the second concentration being less than or equal to 5%, the ratio being defined as uniformity of the second concentration in a central region within 60 mm from a center of the second main surface,
the central region having an arithmetic mean roughness of less than or equal to 0.5 nm.

2. The silicon carbide epitaxial substrate according to claim 1, wherein the width of the transition region is less than or equal to 0.5 μm.

3. The silicon carbide epitaxial substrate according to claim 1, wherein the uniformity of the second concentration is less than or equal to 3%.

4. The silicon carbide epitaxial substrate according to claim 1, wherein the arithmetic mean roughness of the central region is less than or equal to 0.3 nm.

5. The silicon carbide epitaxial substrate according to claim 1, wherein the ratio of the standard deviation of the second concentration to the average value of the second concentration is less than or equal to 20% in a depth direction of the second silicon carbide layer at any point in the central region.

6. (canceled)

7. The silicon carbide epitaxial substrate according to claim 1, wherein a conductivity type of the carriers is n type.

8. A method for manufacturing a silicon carbide semiconductor device, the method comprising:
preparing the silicon carbide epitaxial substrate according to claim 1; and
processing the silicon carbide epitaxial substrate.
